(19) United States
(12) Patent Application Publication
(10) Pub. No.: US 2004/0214391 A1
(43) Pub. Date: Oct. 28, 2004

(54) Method for fabricating bottle-shaped trench capacitor

(75) Inventors: Yi-Nan Chen, Taipei (TW); Hsin-Chuan Tsai, Taoyuan (TW)

Correspondence Address: QUINTERO LAW OFFICE, 1617 BROADWAY, 3RD FLOOR, SANTA MONICA, CA, 90404, US

(73) Assignee: Nanya Technology Corporation

(21) Appl. No.: 10/628,899

(22) Filed: Jul. 28, 2003

(30) Foreign Application Priority Data
Apr. 23, 2003 (TW) 92109460

(51) Int. Cl. H01L 21/8242

(52) U.S. Cl. 438/243

(57) ABSTRACT

A method for fabricating a bottle-shaped trench capacitor. A first conductive layer surrounded by a doped layer is filled in the lower portion of a trench in a substrate. A buried bottom plate is formed in the substrate near the doped layer by a heat treatment. A collar insulating layer is formed over the sidewall of the upper portion of the trench. The first conductive layer and the doped layer are removed using the collar insulating layer as a mask, and then a portion of the doping region is etched to form a bottle-shaped trench. A rugged polysilicon layer and a capacitor dielectric layer are conformably formed in the lower portion of the trench which is subsequently filled with a second conductive layer to serve as a top plate.

### BACKGROUND OF THE INVENTION

1. Field of the Invention

The present invention relates in general to a method for fabricating a semiconductor device, more particularly, to a method for fabricating a bottle-shaped trench capacitor.

2. Description of the Related Art

Typically, the capacitors most widely used in dynamic random access memory (DRAM) comprise two conductive layers (electrode plates) having an insulating layer in between. The ability to store the electric charge of a capacitor depends on the thickness of the insulating layer, surface area of the electrode plate and the electrical characteristics of the insulation material.

Due to recent demand for reduced size of semiconductor elements, for enhancing integration of integrated circuits, the area of cells in a memory device must continuously be reduced to support a larger number of memory cells, thereby increasing integration. Meanwhile, the electrode plates of a capacitor in a memory cell must have a sufficiently large surface area to store adequate electrical charge.

Nevertheless, as the size of elements is continuously reduced, trench storage node capacitance of DRAM has also decreased. As a result, storage capacitance must be increased to maintain good operating performance in memory devices. Currently, the method for increasing storage capacitance for DRAMs increases the width of the bottom of the trench, thereby increasing surface area to form a bottle-shaped trench capacitor.

The above method is carried out by selective oxidation of the upper portion of a trench to form a collar oxide layer to protect the upper portion of the trench. Next, the lower portion of the trench is wet-etched to form a bottle-shaped trench having a greater diameter than the upper portion of the trench.

In a conventional process, a trench is formed by isotropic dry etching on a semiconductor substrate having a pad stack layer comprised of an oxide layer and a nitride layer formed thereon. Next, a nitride layer, an oxide layer, polysilicon layer and another oxide layer are sequentially formed on the pad stack layer and the trench. Nevertheless, the multiple deposition steps further increase the complexity of the process, thus incurring high production costs and lengthening process time. Hence, a simplified process with high production yield for fabricating bottle-shaped trench capacitors is required. In addition, in order to accomplish next generation, high performance memory devices, a method for increasing capacitance of the bottle-shaped trench capacitors is also required.

### SUMMARY OF THE INVENTION

Accordingly, an object of the present invention is to provide a novel method for fabricating a bottle-shaped trench capacitor, thereby simplifying the process and increasing capacitance of the bottle-shaped trench capacitor.

In order to achieve the object and provide other advantages, the invention utilizes a single deposition step to form an oxide layer serving as an etch stop layer for fabrication of the bottle-shaped trench capacitor and a collar oxide layer of the bottle-shaped trench capacitor. Moreover, the invention utilizes a rugged polysilicon layer formed between the buried bottom plate and the capacitor dielectric layer, thereby increasing the surface area of the bottle-shaped trench.

Adcording to the object of the invention, a method for fabricating a bottle-shaped trench capacitor is provided. First, a substrate having a trench therein is provided. Next, the lower portion of the trench is filled with a first conductive layer surrounded by a doped layer. Next, a conformable insulating layer is formed overlying the substrate and the inner surface of the upper portion of the trench to cover the first conductive layer and the doped layer. A doping region is formed in the substrate near the doped layer by a heat treatment to serve as a buried bottom plate. Next, the insulating layer is anisotropically etched to form a collar insulating layer over the sidewall of the upper portion of the trench. Next, the first conductive layer and the doped layer are successively removed using the collar insulating layer as a mask to expose the surface of the doping region. Next, a portion of the exposed doping region is etched to form a bottle-shaped trench. Next, a conformable rugged polysilicon layer and a conformable capacitor dielectric layer are successively formed in the lower portion of the trench. Next, the lower portion of the trench is filled with a second conductive layer to serve as a top plate. Finally, a third conductive layer and a fourth conductive layer are formed overlying the second conductive layer to fully fill the bottle-shaped trench.

The first conductive layer can be a polysilicon layer, and the second, third, and fourth conductive layers can be doped polysilicon layers.

Moreover, the doped layer can be arsenic silicate glass (ASG), and the insulating layer can be tetraethyl orthosilicate (TEOS) oxide.

Moreover, the heat treatment is performed at about 900 to 1100° C.

### DESCRIPTION OF THE DRAWINGS

The present invention will become more fully understood from the detailed description given hereinbelow and the accompanying drawings, given by way of illustration only and thus not intended to be limitative of the present invention.

FIGS. 1a to 1h are cross-sections showing a method for fabricating a bottle-shaped trench capacitor according to the invention.

### DETAILED DESCRIPTION OF THE INVENTION

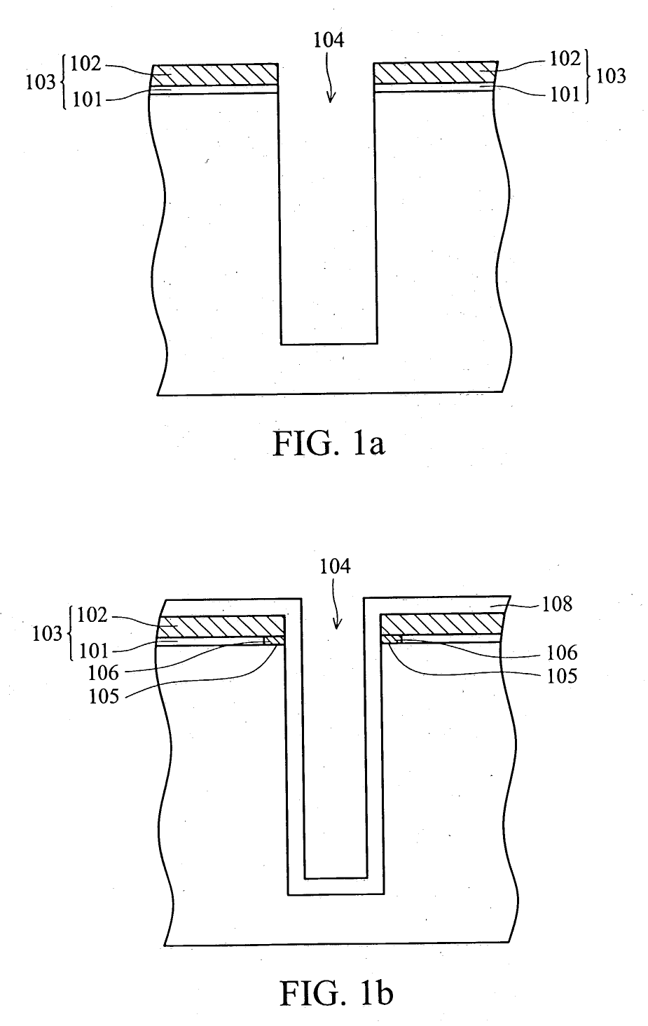

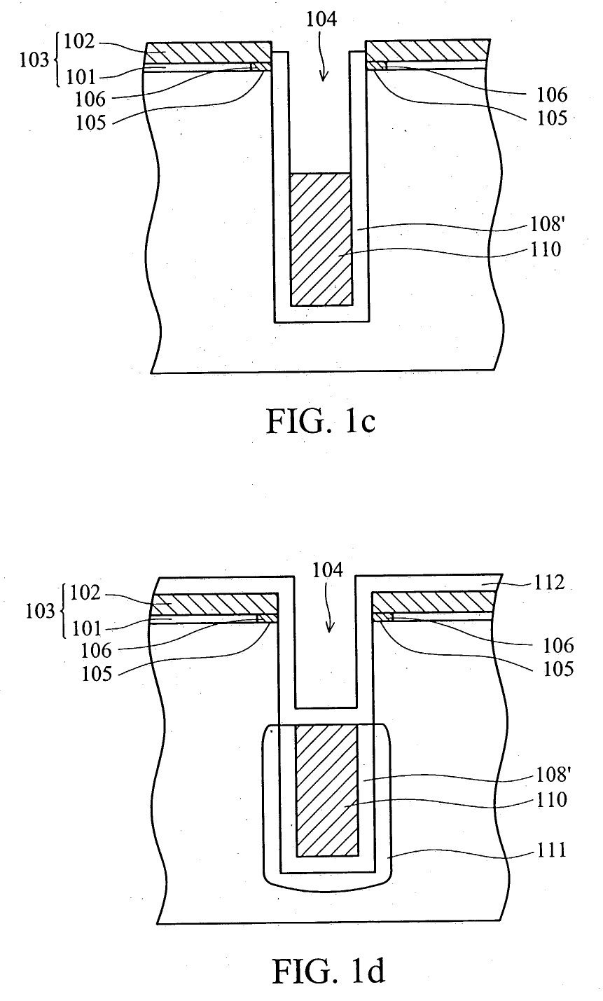

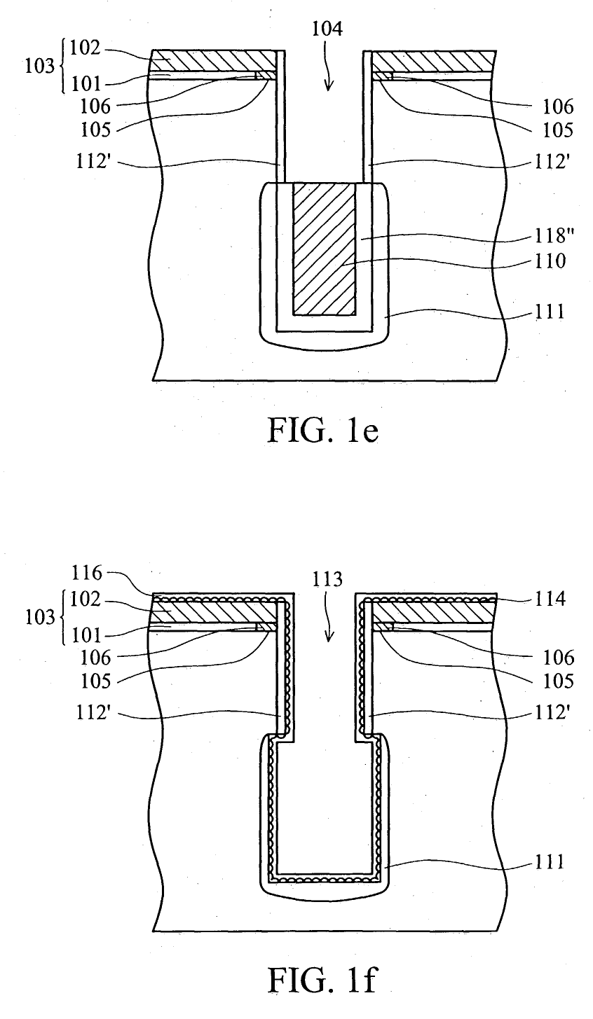

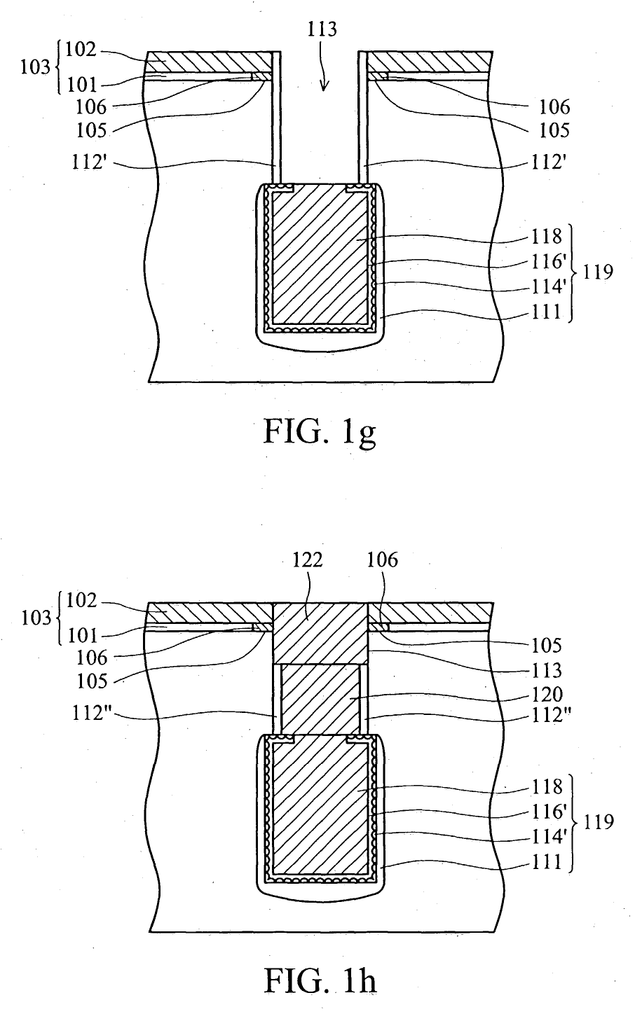

FIGS. 1a to 1h are cross-sections showing a method for fabricating a bottle-shaped trench capacitor in a memory device, such as a dynamic random access memory (DRAM). First, in FIG. 1a, a substrate 100, such as a silicon substrate, is provided. A mask layer 103 is formed on the substrate 100. The mask layer 103 can be composed of a pad oxide layer 101 and a thicker overlying silicon nitride layer 102. In this invention, the pad oxide layer 101 can be formed by thermal oxidation or conventional CVD, which has a thickness of about 100Å. Moreover, the silicon nitride layer 102 overlying the pad oxide layer 101 can be formed by LPCVD using SiCl₂H₂ and NH₃ as reaction sources. Next, a plurality of openings is formed in the masking layer 103 by lithography and etching. Thereafter, anisotropic etching, such as reactive ion etching (RIE), is performed on the substrate 100 using the masking layer 103 as an etch mask to form a plurality of trenches therein. In order to simplify the diagram, only one trench 104 is shown.

Next, in FIG. 1b, optionally, the pad oxide layer 101 is isotropically etched by buffer hydrofluoric (BHF) acid to form a recess 105 with a predetermined depth of about 15 to 40Å. Next, silicon oxide 106 is filled into the recess 105 to protect the pad oxide layer 101 in the subsequent etching, thereby preventing silicon nitride layer 102 from peeling due to degraded adhesion. Thereafter, a conformable insulating layer 108 is formed overlying the masking layer 103 and the inner surface of the trench 104 by conventional deposition, such as chemical vapor deposition (CVD). In the invention, the doped layer can be an arsenic-doped or arsenic silicate glass (ASG) layer, which has a thickness of about 200 to 400Å.

Next, in FIG. 1c, a conductive layer (not shown), such as a polysilicon layer, is deposited on the doped layer 108 and fills the trench 104 by conventional deposition, such as CVD. Subsequently, the excess conductive layer and doped layer 108 overlying the masking layer 103 are successively removed by polishing, such as chemical mechanic polishing (CMP) to leave a portion of conductive layer and doped layer 108′. Next, the remaining conductive layer in the trench 104 is further etched back to a predetermined depth of about 1 μm, thereby leaving a portion of conductive layer 110 in the lower portion of the trench 104.

Next, in FIG. 1d, the doped layer 108′ above the conductive layer 110 is removed using the conductive layer 110 as an etch mask to leave a portion of doped layer 108″ surrounding the conductive layer 110 in the lower portion of the trench 104. Next, a conformable insulating layer 112 is deposited overlying the masking layer 103 and the inner surface of the upper portion of the trench by low-pressure CVD (LPCVD) to cover the conductive layer 110 and the doped layer 108″. In the invention, the insulating layer 112 can be a tetraethyl orthosilicate (TEOS) oxide layer, which has a thickness of about 100 to 300Å.

Next, a heat treatment is performed on the substrate according to the FIG. 1d, thereby diffusing the dopant, such as arsenic, in the doped layer 108″ into the adjacent substrate 100 by a drive-in process to form a doping region 111 therein. The doping region 111 is used as a buried bottom plate. In the invention, the heat treatment is performed at about 900 to 1100° C., and preferably 1050° C.

Next, in FIG. 1e, the insulating layer 112 overlying the masking layer 103 and that in the bottom of trench 104 (overlying the conductive layer 110) are removed by anisotropic etching, such as RIE, to form a collar insulating layer 112′ over the sidewall of the upper portion of the trench 104 and expose the conductive layer 110 and a portion of doped layer 108″.

Next, in FIG. 1f, the conductive layer 110 and the doped layer 108″ are successively removed using the collar insulating layer 112′ as an etch mask to expose the surface of the doping region 111. In the invention, the conductive layer 110 in the trench 104 is first removed by dry etching, and then the doped layer 108″ is removed by vapor hydrofluoric (VHF) acid. Subsequently, isotropic etching is performed using the collar insulating layer 112′ as an etch mask and using NH4OH as an etchant to remove a portion of the exposed doping region 111, thereby forming a bottle-shaped trench 113 having a greater diameter at the lower portion.

Next, a conformable rugged polysilicon (hemispherical grained silicon (HSG)) layer 114 is formed overlying the masking layer 103 and the inner surface of the bottle-shaped trench 113 by conventional deposition, such as LPCVD, at about 565 to 585° C., thereby increasing the surface area of buried bottom plate 111. Thereafter, gas phase doping (GPD) is performed on the rugged polysilicon layer 114 to reduce the concentration difference between the undoped collar insulating layer 112′ and the doped polysilicon layer 114. Next, a conformable dielectric layer 116 is formed over the rugged polysilicon layer 114 by, for example, LPCVD. In the invention, the dielectric layer 116 can be a doped silicon nitride layer or a silicon nitride/silicon oxide (NO) or silicon oxide /silicon nitride/silicon oxide (ONO) staking layer.

Next, in FIG. 1g, a conductive layer (not shown), such as a doped polysilicon layer, is formed overlying the masking layer 103 and fills the bottle-shaped trench 113 by conventional deposition, such as CVD. The conductive layer is subsequently etched to leave a portion of the conductive layer 118 in the lower portion of the bottle-shaped trench 113 to serve as a top plate. Thereafter, the exposed dielectric layer 116 above the conductive layer 118 is removed by hot H₃PO₄ or other suitable solution to leave a portion of the dielectric layer 116′ in the lower portion of the bottle-shaped trench 113 to serve as a capacitor dielectric layer. The rugged polysilicon layer 114 above the capacitor dielectric layer 116′ is removed by RIE using the collar insulating layer 112′ as an etch stop layer to leave a portion of the rugged polysilicon layer 114′ in the lower portion of the bottle-shaped trench 113, thereby completing the fabrication of the bottle-shaped trench capacitor 119 of the invention.

Finally, in FIG. 1h, a conductive layer (not shown), such as a doped polysilicon layer, is formed overlying the masking layer 103 and fills the upper portion of the bottle-shaped trench 113 (overlying the trench capacitor 119) by conventional deposition, such as CVD. Next, the conductive layer is etched to leave a portion of the conductive layer 120 only in the bottle-shaped trench 113 to serve as a first wiring layer. Another conductive layer (not shown), such as a doped polysilicon layer, is subsequently formed overlying the masking layer 103 and fills the bottle-shaped trench 113. Next, the excess conductive layer over the bottle-shaped trench 113 is removed by polishing, such as CMP, to leave a portion of the conductive layer 122 overlying the first wiring layer 120 in the bottle-shaped trench 113 to serve as a second wiring layer.

According to the invention, only a single deposition step is performed to form the collar oxide layer, which also serves an etch stop layer for fabrication of the bottle-shaped trench capacitor. Accordingly, the process for fabricating the bottle-shaped trench capacitor can be simplified, thereby increasing throughput and reducing fabrication cost. Moreover, the rugged polysilicon layer is additionally formed between the buried bottom plate and the capacitor dielectric layer, which can increase the surface area of the bottle-shaped trench, thereby increasing the capacitance of the bottle-shaped trench capacitor. That is, the performance of the memory device can be further enhanced.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for fabricating a bottle-shaped trench capacitor, comprising the steps of:
forming a trench in a substrate;
filling a lower portion of the trench with a first conductive layer surrounded by a doped layer;
forming a conformable insulating layer overlying the substrate and an inner surface of the upper portion of the trench to cover the first conductive layer and the doped layer;
performing a heat treatment on the substrate to form a doping region in the substrate near the doped layer to serve as a buried bottom plate;
anisotropically etching the insulating layer to form a collar insulating layer over a sidewall of an upper portion of the trench;
successively removing the first conductive layer and the doped layer using the collar insulating layer as a mask to expose the surface of the doping region;
etching a portion of the exposed doping region to form a bottle-shaped trench;
successively forming a conformable rugged polysilicon layer and a conformable capacitor dielectric layer in the lower portion of the trench; and
filling the lower portion of the trench with a second conductive layer to serve as a top plate.

2. The method as claimed in claim 1, further successively forming a third conductive layer and a fourth conductive layer overlying the second conductive layer.

3. The method as claimed in claim 2, wherein the third and fourth conductive layers are doped polysilicon layers.

4. The method as claimed in claim 1, wherein the first conductive layer is a polysilicon layer.

5. The method as claimed in claim 1, wherein the doped layer is an arsenic silicate glass (ASG) layer.

6. The method as claimed in claim 5, wherein the doped layer is removed by vapor hydrofluoric (VHF) acid.

7. The method as claimed in claim 1, wherein the insulating layer is tetraethyl orth6silicate (TEOS) oxide.

8. The method as claimed in claim 1, wherein the heat treatment is performed at about 900 to 1100° C.

9. The method as claimed in claim 1, wherein the portion of the exposed doping region is etched by NH₄OH.

10. The method as claimed in claim 1, wherein the second conductive layer is a doped polysilicon.

11. The method as claimed in claim 1, wherein the capacitor dielectric layer comprises a silicon nitride layer.

12. The method as claimed in claim 1, further performing a gas phase doping (GPD) after the rugged polysilicon layer is formed.

13. A method for fabricating a bottle-shaped trench capacitor, comprising the steps of:
providing a substrate covered by a masking layer having an opening therein;
etching the substrate under the opening to form a trench therein;
filling a lower portion of the trench with a polysilicon layer surrounded by a doped silicon oxide layer;
forming a conformable insulating layer overlying the masking layer and an inner surface of the upper portion of the trench to cover the polysilicon layer and the doped silicon oxide layer;
performing a heat treatment on the substrate to form a doping region in the substrate near the doped silicon oxide layer to serve as a buried bottom plate;
anisotropically etching the insulating layer to form a collar insulating layer over a sidewall of an upper portion of the trench;
successively removing the polysilicon layer and the doped silicon oxide layer using the collar insulating layer as a mask to expose the surface of the doping region;
etching a portion of the exposed doping region to form a bottle-shaped trench;
successively forming a conformable rugged polysilicon layer and a conformable capacitor dielectric layer in the lower portion of the trench;
filling the lower portion of the trench with a doped polysilicon layer to serve as a top plate;
successively forming a second doped polysilicon layer and a third doped polysilicon layer overlying the first doped polysilicon layer.

14. The method as claimed in claim 13, wherein the masking layer is composed of a pad oxide layer and an overlying silicon nitride layer.

15. The method as claimed in claim 14, before filling the polysilicon layer, further comprising the steps of:
isotropically etching the pad oxide layer to form a recess with a predetermined depth; and
filling the recess with silicon nitride.

16. The method as claimed in claim 15, wherein the pad oxide layer is etched by buffer hydrofluoric (BHF) acid.

17. The method as claimed in claim 15, wherein the predetermined depth is about 15 to 40Å.

18. The method as claimed in claim 13, wherein the doped silicon oxide layer is an arsenic silicate glass (ASG) layer.

19. The method as claimed in claim 18, wherein the doped silicon oxide layer is removed by vapor hydrofluoric (VHF) acid.

20. The method as claimed in claim 13, wherein the insulating layer is tetraethyl orthosilicate (TEOS) oxide.

21. The method as claimed in claim 13, wherein the heat treatment is performed at about 900 to 1100° C.

22. The method as claimed in claim 13, wherein the portion of the exposed doping region is etched by NH₄OH.

23. The method as claimed in claim 13, wherein the capacitor dielectric layer comprises a silicon nitride layer.

24. The method as claimed in claim 13, further performing a gas phase doping (GPD) after the rugged polysilicon layer is formed.
